(19) United States
(12) Patent Application Publication
(10) Pub. No.: US 2022/0352845 A1
(43) Pub. Date: Nov. 3, 2022

(54) DEVICE FOR GENERATING ELECTRICITY

(71) Applicant: CLEARVUE TECHNOLOGIES LTD, West Perth (AU)

(72) Inventors: Jamie LYFORD, West Perth (AU); Victor ROSENBERG, West Perth (AU); Steven COONEN, Grass Valley, CA (US)

(73) Assignee: CLEARVUE TECHNOLOGIES LTD, West Perth (AU)

(21) Appl. No.: 17/754,401

(22) PCT Filed: Oct. 1, 2020
(86) PCT No.: PCT/AU2020/051052

§ 371 Date: Mar. 31, 2022

(30) Foreign Application Priority Data
Oct. 1, 2019 (AU) 2019903698
Nov. 12, 2019 (AU) 2019904261

(51) Int. Cl. H02S 20/26; E06B 9/24

(52) U.S. Cl. CPC H02S 20/26; E06B 9/24; E06B 2009/2476

(57) ABSTRACT

The present disclosure provides a device for generating electricity. The device comprises a panel having an area that is transparent for at least a portion of visible light and having a light receiving surface. The panel comprises at least one series of solar cells, each solar cell having opposite major surfaces having opposite electrical polarities, each solar cell overlapping another one of the solar cells and being electrically connected in series. The at least one series of solar cells is positioned along and in the proximity of an edge of the panel, along the area that is transparent for at least a portion of visible light and substantially parallel the light receiving surface of the panel.

### FIELD OF THE INVENTION

The present disclosure relates to a device for generating electricity and relates particularly, though not exclusively, to a panel, such a panel for a window comprising solar cells.

### BACKGROUND OF THE INVENTION

Buildings such as office towers, high-rise housings and hotels use large amounts of exterior window panelling and/or facades which incorporate glass panelling.

Overheating of interior spaces, such as spaces that receive sunlight through such window panels, is a problem that may be overcome using air conditioners. A large amount of energy is globally used to operate air conditioners.

PCT international applications numbers PCT/AU2012/000778, PCT/AU2012/000787 and PCT/AU2014/000814 (owned by the present applicant) disclose a spectrally selective panel that may be used as a windowpane and that is largely transmissive for visible light, but diverts a portion of incident infrared light to side portions of the panel where it is absorbed by solar cells to generate electricity.

It is to be understood that, if any prior art publication is referred to herein, such reference does not constitute an admission that the publication forms a part of the common general knowledge in the art, in Australia or any other country.

### SUMMARY OF THE INVENTION

The present invention provides in a first aspect a device for generating electricity, the device comprising:

a panel having an area that is transparent for at least a portion of visible light and having a light receiving surface; and

at least one series of solar cells, each solar cell having opposite major surfaces having opposite electrical polarities, each solar cell overlapping another one of the solar cells therein and being electrically connected in series;

wherein the at least one series of solar cells is positioned along and in the proximity of an edge of the panel, along the area that is transparent for at least a portion of visible light and substantially parallel the light receiving surface of the panel.

The panel may be a panel of a window and the device may further comprise a frame structure for supporting the panel. In this embodiment the device may be provided in the form of a window unit for a building, such as an insulated glass unit.

The solar cells of the series of solar cells are positioned in an overlapping relationship or in a shingle-like arrangement, which has advantages for window applications. In such applications space is limited and solar cells should be as small as possible. Embodiments of the present invention avoid gaps between adjacent solar cells. Consequently, a conversion efficiency per area can be increased. Further, there is no need for top contacts or fingers which would otherwise reduce an area of each solar cell available for receiving photons for generating electricity.

The solar cells of the at least one series of solar cells may have a front surface portion which is directly or indirectly bonded to the panel in a manner such that an airgap between the solar cells and the panel is avoided. An additional adhesive may be used for the bonding. In one embodiment the adhesive has a refractive index that at least approximates that of the panel material, which may for example be glass or a suitable polymeric material. Alternatively, the solar cells may have an outer layer of a polymeric material, such as Polyvinyl butyral (PVB) or ethylene-vinyl acetate (EVA) or another suitable material. The solar cells are in this embodiment directly bonded to the panel. For example, if the solar cells comprise a layer of PVB or EVA or another suitable material, that material may be slightly softened and then adhered directly to the panel. As a gap between the panel and the solar cells is avoided, light intensity losses of light propagating from the panel into the solar cell are reduced.

The device may comprise a plurality of the series of solar cells and which may be positioned around (and may surround) the area that is transparent for at least a portion of visible light. The plurality of the series of solar cells may be positioned in the proximity of edges of the panel such that the panel is largely transparent for at least a portion of visible light and the area that is transparent for at least a portion of visible light is a central area and at 5, 10, 15, 20, 50, 100 or even 500× larger than an area of the panel at which the series of the solar cells are positioned.

The at least one series of the solar cells typically is positioned at a panel surface that is opposite the light receiving surface such that light received by the light receiving surface propagates through at least a portion of the panel before reaching the at least one series of solar cells.

The panel may have four edges and at least one of the series of solar cells may be positioned at each edge of the panel.

In one specific embodiment the at least one series of solar cells comprises at least two series of solar cells which may be positioned at adjacent edges of the panel and which may be electrically connected in series or in parallel.

In one embodiment adjacent ones of the at least two series of the solar cells may be oriented at an angle relative to each other (such as an angle in the range of 80-100 degrees or substantially 90 degrees) and may face the light receiving surface. At least one solar cell of the at least two series of solar cells may overlap with, and may be electrically series connected to, at least one solar cell of an adjacent one of the at least two series of solar cells whereby the at least two series of solar cells are electrically series connected. Alternatively, at least one solar cell of the at least two series of solar cells may overlap with, and may be electrically insulated from, at least one solar cell of an adjacent one of the at least two series of solar cells and the at least two series of solar cells may be electrically connected in parallel.

In one specific example a solar cell positioned at an end of one of the at least two series of solar cells overlap a solar cell of the adjacent one of the at least two series of solar cells in a manner such that the adjacent series of solar cells form an angle, such as an angle of substantially 90 degrees.

In one specific embodiment the panel has a substantially right angle and has a generally rectangular shape. Adjacent series of solar cells may be positioned at adjacent edges of the panel such that the adjacent series of solar cells form a substantially right angle. In this embodiment a solar cell positioned at an end of adjacent series of solar cell may form an overlapping relationship with a side surface of a solar cell positioned at an end of the adjacent series of solar cells.

In one embodiment adjacent ones of the at least two series of the solar cells are substantially parallel to each other and face the light receiving surface. At least one solar cell of the at least two series of solar cells may overlap with and may or may not be electrically series connected to, at least one solar cell of an adjacent one of the at least two series of solar cells. Further, a first and a second series of the solar cells may be positioned immediately adjacent (and substantially parallel to) each other and all or at least most of the solar cells of the first series may overlap with respective solar cells of the second series. At least some or all of the solar cells of the first series may be electrically isolated or may be electrically connected with the respective solar cells of the second series. In one specific embodiment the solar cells of the first series are electrically connected with respective ones of the solar cells of the second series and the solar cells of the second series are electrically series connected. Alternatively, the first and second series of solar cells may be electrically insulated from each other and the solar cells or the first series may be series connected and the solar cells of the second series may be electrically series connected.

The solar cells of the first and second series may be inclined in the same manner and direction. Alternatively, the solar cells of the first and second series may be inclined in a opposite manner and direction. Further, the solar cells of the first and second series may be inclined by the same or different angles relative to a surface normal of the receiving surface.

The panel may be a first panel and the device may comprise a second panel that may be positioned substantially parallel the first panel in a manner such that light received by the light receiving surface of the first panel initially propagates through the first panel before being received by the second panel. The second panel may also have an area that is transparent for at least a portion of visible light.

Each solar cell may have a rear surface portion that is directly or indirectly bonded to the second panel whereby each solar cell of the first series and/or second series may be directly or indirectly bonded to both the first and the second panels and each solar cell is sandwiched between the first and second panels. In this embodiment both the front and also the rear surfaces of the device are surfaces of the first or second panel (which may be glass panels), which has the advantage of protecting the solar cells and also has the advantage of providing reliable (vacuum) sealing surfaces for window application.

The at least one series of solar cells may be at least one series of first solar cells and the device may further comprise at least one series of second solar cells positioned at the second panel. Each second solar cell may have opposite major surfaces having opposite electrical polarities, each second solar cell may overlap with another one of the second solar cells and may or may not be electrically connected in series, wherein the at least one series of second solar cells is positioned along and in the proximity of an edge of the second panel and facing the light receiving surface of the first panel.

The second solar cells may be bonded to the second panel, such as directly bonded, in a manner such that an airgap between the second solar cells and the second panel is avoided.

The second panel may have four edges and may comprise at least one of the series of second solar cells positioned at each edge of the second panel.

In one specific embodiment the at least one series of solar second cells comprises a plurality of series of second solar cells which are oriented at adjacent edges of the second panel. The series of the second solar cells may be oriented at an angle relative to each other (such as an angle in the range of 80-100 degrees or substantially 90 degrees). At least one solar cell of one of the series of second solar cells may overlap with at least one solar cell of an adjacent series. In one specific example a solar cell positioned at an end of one of the series of second solar cells and may overlap with a solar cell of an adjacent series of second solar cells in a manner such that the adjacent series of solar cells form an angle. The overlapping solar cells at the ends of the adjacent series of second solar cells may be electrically connected to each other whereby the adjacent series of solar cells are electrically series connected. Alternatively, the overlapping solar cells at the ends of the adjacent series of second solar cells may be electrically insulated from each other and the adjacent series of solar cells may be electrically connected in parallel.

In one specific embodiment the second panel has a substantially right angle and a generally rectangular shape.

At least two of series of second solar cells may be positioned at adjacent edges of the second panel such that adjacent series form a substantially right angle. In this embodiment a second solar cell positioned at an end of one of the series of second solar cells may overlap with a side surface of a second solar cell positioned at an end of an adjacent series of second solar cells.

The second panel may further comprise a diffractive element and/or luminescent material in order to facilitate redirection of incident infrared light to edges of the second panel.

Further, the device may comprise at least one series of third solar cells that is positioned at at least one edge surface of the second panel and oriented substantially perpendicular to a major surface of the second panel whereby the at least one series of third solar cells is positioned substantially perpendicular to the series of first solar cell at the first panel and the series of second solar cells at the second panel. The series of third solar cells is positioned to receive at least a portion light redirected by the diffractive element and/or the luminescent material. The deflection of infrared radiation by the diffractive element has the further advantage that transmission of infrared radiation into buildings (when the panel is used as a window pane) can be reduced, which consequently reduces overheating of spaces within the building and can reduce costs for air conditioning.

The solar cells may be silicon-based solar cells, but may alternatively also be based on any other suitable material, such CIGS or CIS, GaAs, CdS or CdTe.

In one specific embodiment the solar cells of the series of first solar cells and the series of second solar cells are silicon-based and the solar cells of the series of third solar cells are CIS- or CIGS-based.

The invention will be more fully understood from the following description of specific embodiments of the invention. The description is provided with reference to the accompanying drawings.

### BRIEF DESCRIPTION OF THE DRAWINGS

FIG. 1 is a schematic top view of a device for generating electricity in accordance with an embodiment of the present invention;

FIG. 2 is a schematic cross-sectional representation of a component of the device for generating electricity in accordance with an embodiment of the present invention;

FIG. 3 is a schematic top view of a portion of the device for generating electricity shown in FIG. 1; and

FIGS. 4 and 5 are schematic cross-sectional representations of a portion of the device in accordance with an embodiment of the present invention.

### DETAILED DESCRIPTION OF EMBODIMENTS

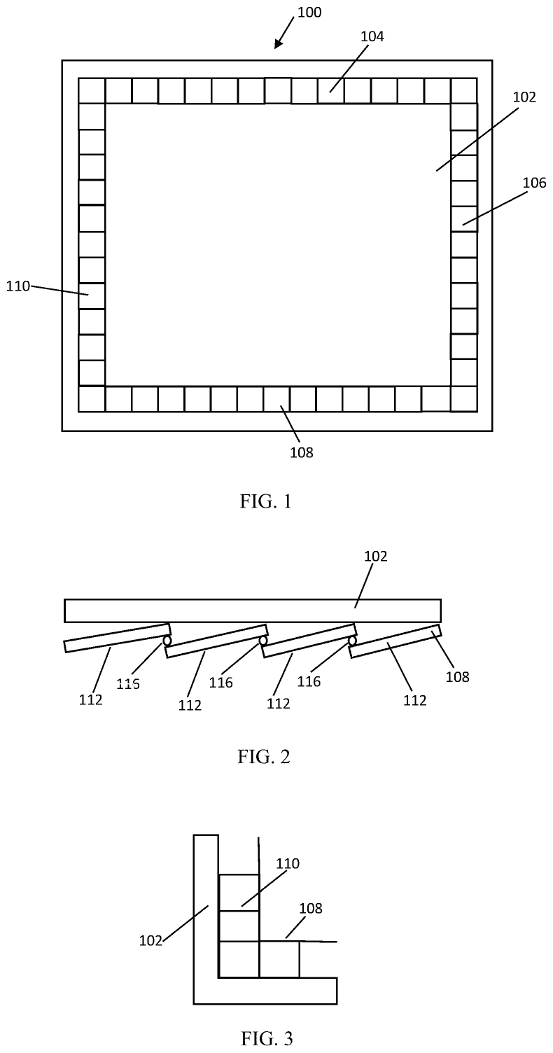

Referring initially to FIG. 1, there is shown a schematic top view of a device for generating electricity 100 in accordance with an embodiment of the present invention. The device 100 comprises a panel 102 and in this embodiment four series of solar cells 104 106, 108,110 are positioned at respective edges of the panel 102. The four series of solar cells 104 106, 108,110 face a light receiving surface of the panel and together surround an area of the panel that is at least largely transmissive for light. The panel 102 may for example form a panel of a window of a building or another structure and the four series of solar cells 104 106, 108,110 may be positioned at a frame structure that supports the panel 102 and one or more other panels to for a window unit.

The panel 102 may have any shape, but in one specific embodiment is rectangular and may be square. The panel 102 may be formed from suitable glass or polymeric materials.

FIG. 2 shows a cross-sectional representation of a portion of the panel 102 and a portion of the series of solar cells 108. The solar cells 112 of the series of solar cells 108 and arranged in an overlapping relationship and electrically coupled using a conductive adhesive 116. The solar cells 112, have opposite major surfaces and which have different polarities and are oriented such that only surfaces of the same polarities face the panel 102. The conductive adhesive 116 couples a back face of one of the solar cells 112 with a front face of an adjacent solar cell 112. Consequently, the solar cells of the series of solar cells are electrically series connected.

The solar cells 112 are adhered directly to the panel 102. In this example the solar cells 112 comprise outer ETA layers. Prior to adhering the solar cells 112 to the panel 102, the ETA is slightly softened (by the careful application of heat) and then the solar cells 112 are pressed against the panel 102. Once the softened ETA has hardened again, the solar cells are adhered to the panel 102.

FIG. 2 is a schematic representation only. A person skilled in the art will understand that the solar cells 112 relatively long compares to their thickness and consequently the solar cells 112 are substantially parallel the panel 102 even though they are arranged in an overlapping (shingled) relationship.

Turning now to FIG. 3, there is shown a schematic representation of a corner region of the of the device shown in FIG. 1. FIG. 3 shows a portion of the panel 102 and a portion of adjacent series of solar cells 108, 110. In this embodiment the series of the solar cells 108, 110 form a right angle and an end surface of a solar cell positioned at end of the series 110 of solar cells overlaps with a side portion of a solar cell positioned at an end of the other series 108 of solar cells. The overlapping portions of the solar cells are electrically series connected using a conductive adhesive 116 in the same manner as illustrated above with reference to FIG. 2. In a variation of the described embodiment the overlapping portions of the solar cells at the ends of the series 108, 110 are electrically insulated from each other and the series of solar cells 108, 110 are electrically parallel connected.

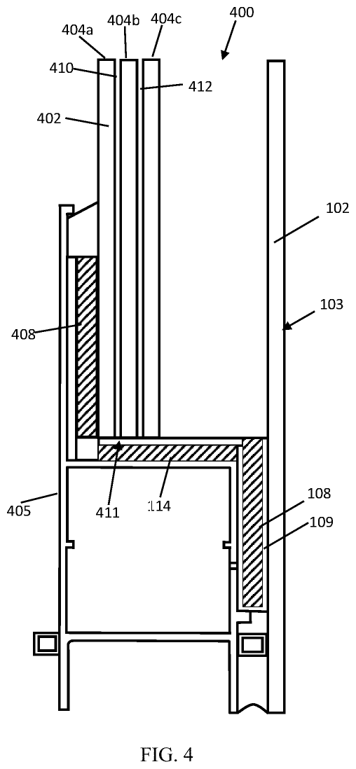

Turning now to FIG. 4, there is shown a cross-sectional view of a portion of a window unit in accordance with an embodiment of the present invention. The window unit 400 comprises the panel 102 with the series of (shingled) solar first cells 104, 106, 108 and 110, which are encapsulated by a layer of ETA 109. The panel 102 has a light receiving surface 103. In this embodiment the panel 102 is a first panel and the window unit 400 also comprises a second panel 402, which is positioned parallel, and spaced apart from, the first panel 102. The second panel 402 has series of solar cells 404 directly adhered to it in the same manner as illustrated above for the first panel 102 and with reference to FIGS. 1, 2 and 3. In this embodiment the panels 102 and 402 are rectangular and each comprise four series of solar cells that are adhered at edge portions of the panels 102, 404 and positioned as illustrated in FIG. 1. The series of solar cells comprise overlapping (shingled) solar cells as illustrated in FIG. 2 and corners are formed in a manner as illustrated above in FIG. 3 for the first panel 102.

The window unit 400 also comprises a frame structure 405 that is arranged to hold the panels 102 and 402 and the series of solar cells in position.

The panels 102 and 404 comprise in this embodiment respective panes of glass that are each largely transmissive for visible light. In an embodiment the glass panes that form the panels 102 and 404 are formed of low iron ultra-clear glass pane, with the panel 404 additionally having a low-E coating.

In the embodiment shown in FIG. 4 the panel 404 is a laminate structure having three sub-panes 404a, 404b and 404c. The sub-pane 404a is formed of low iron ultra-clear glass having a thickness of 4 mm, and second and third panes 404b and 404c are each formed from ultra-clear glass having a thickness of 4 mm. The sub-panes 404a, 404b and 404c mate with each other to form a stack of the sub-panes substantially parallel to one another. Disbursed between panes 404a and 404b is an interlayer 410 of polyvinyl butyral (PVB). A PVB interlayer 412 is also located between sub-pane 404b and 404c, but PVB interlayer 412 also includes a light scattering element. In this embodiment the light scattering element comprises a luminescent scattering powder embedded in the PVB, which also an epoxy that provides adhesive. The panel 404 also includes a diffraction grating that is arranged to facilitate redirection of light towards edge region of the panel 404 (i.e. towards the frame 20) and guiding of the light by total internal reflection.

It should be appreciated that the panel 404 could have any number of panes with any number of interlayers. In some embodiments the panel 404 may comprise a single piece of optically transmissive material such as glass.

The panel 404 has an edge 411 that has a plane which is transverse to the light receiving surface 103. In the embodiment of FIG. 2, the angle between the edge 411 and the light receiving surface 103 is 90°.

The window unit 400 also has series of third solar cells 414. The series of third solar cells 414 face the edge 411 and a cavity between the first panel 102 and the second panel 404. The series of third solar cells 414 substantially surround the second panel 404 and are positioned to receive light that is redirected by the scattering material and/or the diffractive element (not shown) to the edges 416 of the second panel 404. Further, the series of third solar cells 414 also receives light at an area which faces the cavity between the first panel 102 and the second panel 404.

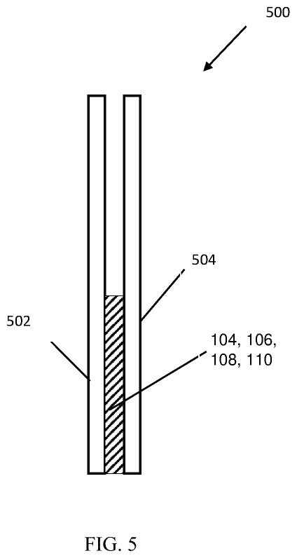

FIG. 5 shows a device for generating electricity in accordance with a further embodiment of the present invention. FIG. 5 shows the device 500 having a first panel 502 and a second panel 504. The first and second panels 502, 504 are transmissive for at least 70% of incident visible light (limited by the transmissivity of the panel material, such as glass). The device 500 comprises the above-described series of solar cells 104 106, 108, 110 (only the series 104 is shown in FIG. 5) positioned at respective edges of the panels 502, 504.

The solar cells 104 106, 108, 110 each have light receiving surface portions facing the panel 502 and adhered to the panel 502 such that no air gap is present between the solar cells 104, 106, 108, 110 and the panel 502. Further, the solar cells 104, 106, 108, 110 each have a rear surface portions facing the panel 504 and adhered to the panel 504. In this example the solar cells 104, 106, 108, 110 comprise outer polyvinyl butyral (PVB) or ethylene-vinyl acetate (EVA) layers at the front surfaces. A sheet of excluded-volume-branched-polymers (EVB) or Ethylene tetrafluoroethylene (ETFE) is placed between the panels 502 and 504 such that the sheet is also positioned between the rear surfaces of the solar cells 104, 106, 108, 110 and panel 504. Prior to adhering the solar cells 104, 106, 108, 110 to the panels 502, 504 (and the panels 502, 504 to each other) the PVB, ETA, EVB or ETFE is slightly softened (by the careful application of heat) and then the panel 502, 504 are pressed together such that the solar cells 104, 106, 108, 110 are positioned between the panels 502, 504. Once the softened PVB, ETA, EVB or ETFE has hardened again, the solar cells are sandwiched between, and adhered to, the panels 502, 504 without the need of an additional adhesive whereby a laminated structure is formed. The panels 502, 504 protect the solar cells 104, 106, 108, 110 and also provide reliable sealing surfaces at both front and rear sides of the device, which is advantageous for window applications.

In the present embodiment, the series of first and second solar cells 104, 106, 108, 110, 408 may be silicon-based solar cells, but can alternatively also be based on any other suitable material such CdS, CdTe, GaAs, CIS or CIGS. The series of third solar cells 414 may be CIS or CIGS-based, but may alternatively also be based on any other suitable material such SI, CdS, CdTe, or GaAs.

Whilst a number of specific embodiments have been described, it should be appreciated that the disclosed unit 400 maybe embodied in many other forms. For example, the unit 400 may not necessarily be rectangular, but may alternatively have any other suitable shape (such as for example round or rounded). Further, the panel 404 may comprise any suitable number of sub-panels. Further, the window unit may comprise a third panel such that a triple glazing unit is formed.

Any discussion of the background art throughout this specification should in no way be considered as an admission that such background art is prior art, nor that such background art is widely known or forms part of the common general knowledge in the field in Australia or worldwide.

Further, a person skilled in the art will appreciate that modifications of the described embodiments are possible. For example, the solar cells within each series may not necessarily be series connected. The device may also comprise adjacent and substantially parallel series of solar cells. The adjacent and substantially parallel series of solar cells may overlap such that each solar cell of a first series overlaps with a (or a respective) solar cell an immediate adjacent and substantially parallel series of the solar cells. The solar cells of a first series may be electrically series connected or alternatively may be electrically isolated from each other and electrically connected with the respective solar cells of a second series. For example, the solar cells of the first series may be electrically connected with respective ones of the solar cells of the second series and the solar cells of the second series are electrically series connected. The solar cells of the first and second series may be inclined in the same manner and direction. Alternatively, the solar cells of the first and second series may be inclined in a opposite manner and direction. Further, the solar cells of the first and second series may be inclined by the same or different angles relative to a surface normal of the receiving surface.

1. A device for generating electricity, the device comprising:
a panel having an area that is transparent for at least a portion of visible light and having a light receiving surface; and
at least one series of solar cells, each solar cell having opposite major surfaces having opposite electrical polarities, each solar cell overlapping another one of the solar cells therein and being electrically connected in series;
wherein the at least one series of solar cells is positioned along and in the proximity of an edge of the panel, along the area that is transparent for at least a portion of visible light and substantially parallel the light receiving surface of the panel.

2. (canceled)

3. The device of claim 1 wherein the device is provided in the form of a window unit.

4. The device of claim 1 wherein the solar cells of the at least one series of solar cells are positioned in a shingle-like arrangement.

5. The device of claim 1 wherein solar cells of the at least one series of solar cells are bonded to the panel in a manner such that an airgap between the solar cells and the panel is avoided.

6. The device of claim 5 wherein the solar cells of the at least one series of solar cells comprise an outer layer of a polymeric material and are directly bonded to the panel.

7. (canceled)

8. The device of claim 1 wherein the at least one series of solar cells is one of a plurality of series of solar cells which are positioned around the area that is transparent for at least a portion of visible light and in the proximity of edges of the panel such that the panel is largely transparent for at least a portion of visible light the area that is transparent for at least a portion of visible light is a central area and at 10 times larger than an area of the panel at which the series of the solar cells are positioned.

9. The device of claim 1 wherein the at least one series of solar cells is one of at least two series of solar cells positioned along adjacent edges of the panel.

10. The device of claim 9 wherein adjacent ones of the at least two series of the solar cells are oriented at an angle relative to each other and substantially parallel to the light receiving surface of the panel and wherein at least one solar cell of the at least two series of solar cells overlaps with at least one solar cell of an adjacent one of the at least two series of solar cells.

11. (canceled)

12. The device of claim 9 wherein the at least one solar cell of the at least two series of solar cells overlaps with at least one solar cell of an adjacent one of the at least two series of solar cells and are electrically connected whereby the at least two series of solar cells are electrically series connected.

13. The device of claim 9 wherein the at least one solar cell of the at least two series of solar cells overlaps with, and is electrically insulated from, at least one solar cell of an adjacent one of the at least two series of solar cells and the at least two series of solar cells are electrically connected in parallel.

14. The device of any one of claim 9 wherein a solar cell positioned at an end of one of the at least two series of solar cells overlaps a solar cell of the adjacent one of the at least two series of solar cells in a manner such that the adjacent series of solar cells form an angle.

15. The device of claim 9 wherein adjacent ones of the at least two series of the solar cells are substantially parallel to each other and face the light receiving surface.

16. The device of claim 15 wherein at least one solar cell of the at least two series of solar cells overlaps with at least one solar cell of an adjacent one of the at least two series of solar cells.

17. The device of claim 9 wherein a first and a second series of the solar cells are positioned immediately adjacent each other and all or at least most of the solar cells of the first series overlap with respective solar cells of the second series of solar cells.

18. The device of claim 17 wherein the solar cells of the first series are electrically connected with respective ones of the solar cells of the second series and the solar cells of the second series are electrically series connected.

19. The device of claim 9 wherein the first and second series of solar cells are electrically insulated from each other and the solar cells of the first series are series connected and the solar cells of the second series are electrically series connected.

20. The device of claim 9 wherein the solar cells of the first and second series are inclined in the same manner and direction.

21. The device of claim 9 wherein the solar cells of the first and second series are inclined in a opposite manner and direction.

22. The device of claim 9 wherein the solar cells of the first and second series are inclined by different angles relative to a surface normal of the receiving surface.

23. (canceled)

24. The device of claim 1 wherein the panel is a first panel and the device comprises a second panel that is positioned substantially parallel the first panel in a manner such that light received by the light receiving surface of the first panel initially propagates through the first panel before being received by the second panel, wherein the second panel has an area that is transparent for at least a portion of visible light.

25-37. (canceled)
